(19) United States
(12) Patent Application Publication
(10) Pub. No.: US 2019/0371766 A1
(43) Pub. Date: Dec. 5, 2019

(54) INTEGRATED CIRCUIT DIE STACKS

(71) Applicant: Intel Corporation, Santa Clara, CA (US)

(72) Inventors: Bin Liu, Shanghai (CN); Zhicheng Ding, Shanghai (CN); She Yong, Shanghai (CN); Aiping Tan, Shanghai (CN); Mao Guo, Shanghai (CN)

(73) Assignee: Intel Corporation, Santa Clara, CA (US)

(21) Appl. No.: 16/462,290

(22) PCT Filed: Dec. 19, 2016
(86) PCT No.: PCT/CN2016/110701

§ 371 Date: May 20, 2019

(51) Int. Cl. H01L 25/065; H01L 23/00; H01L 25/00

(52) U.S. Cl. CPC H01L 25/0657; H01L 23/3128; H01L 24/32; H01L 24/73; H01L 25/50; H01L 24/92; H01L 2225/0651; H01L 2225/06513; H01L 2225/06558; H01L 2225/06565; H01L 2224/32145; H01L 2224/32225; H01L 2224/48227; H01L 2224/48091; H01L 2224/73265; H01L 2224/92247; H01L 24/48

(57) ABSTRACT

Disclosed herein are integrated circuit (IC) die stacks, as well as related apparatuses and methods. For example, in some embodiments, an IC package may include: a package substrate having a substrate conductive contact; a first die coupled to the package substrate, wherein the first die has a first face and an opposing second face, the second face of the first die is between the first face of the first die and the package substrate, and the first die has a first conductive contact at the first face of the first die; a second die coupled to the first die, wherein the second die has a second conductive contact facing the first face of the first die; and a bondwire between the first conductive contact and the substrate conductive contact, wherein the bondwire is also in electrical contact with the second conductive contact.

### BACKGROUND

In some integrated circuit (IC) packages, top faces of the dies may be wirebonded to each other and/or to a package substrate. Conventionally, when such dies are stacked, the dies may be offset from each other in a “zigzag” pattern, or spaced apart by thick films, to accommodate the bondwires extending from the top face of each die.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C are various views of an integrated circuit (IC) device including an example IC package with a die stack, in accordance with some embodiments.

FIG. 2 is a cross-sectional side view of an example die pair conductive structure in a die stack, in accordance with various embodiments.

FIGS. 3A-3C are various views of an IC device including another example IC package with a die stack, in accordance with some embodiments.

FIGS. 4A-4H are cross-sectional side views of various stages in the manufacture of an IC device with a die stack, in accordance with various embodiments.

FIG. 5 is a flow diagram of an example method of manufacturing a die stack, in accordance with various embodiments.

FIGS. 6A-6B are top views of a wafer and dies that may be used in any of the die stacks disclosed herein.

FIG. 7 is a cross-sectional side view of an IC device that may be included in a die of any of the die stacks disclosed herein.

FIG. 8 is a cross-sectional side view of an IC device assembly that may include any of the die stacks disclosed herein.

FIG. 9 is a block diagram of an example computing device that may include any of the die stacks disclosed herein.

### DETAILED DESCRIPTION

Disclosed herein are integrated circuit (IC) die stacks, as well as related apparatuses and methods. For example, in some embodiments, an IC package may include: a package substrate having a substrate conductive contact; a first die coupled to the package substrate, wherein the first die has a first face and an opposing second face, the second face of the first die is between the first face of the first die and the package substrate, and the first die has a first conductive contact at the first face of the first die; a second die coupled to the first die, wherein the second die has a second conductive contact facing the first face of the first die; and a bondwire between the first conductive contact and the substrate conductive contact, wherein the bondwire is also in electrical contact with the second conductive contact.

Some conventional single-side wirebond die stack architectures include offset die stacks in which all of the dies in a stack are arranged with their bond pads facing “up” and disposed proximate to one side of the dies, are coupled together using die attach film between adjacent pairs of dies, and are offset from each other to expose the bond pads to enable cascading wirebonds (from die to die, and from the bottommost die to the package substrate) or direct wirebonds (from each of the dies to the package substrate). The footprint (or “shadow”) of such an offset stack is greater than the footprint of any of the individual dies. To accommodate greater numbers of dies without creating an excessive cantilever, oppositely offset stacks may be stacked on each other to form a “zigzag” pattern with wirebonds extending from opposite “sides” of the whole stack; the footprint of this zigzag stack is typically even larger than the footprint of a single offset stack. Another way to accommodate greater numbers of dies is to stack offset stacks with the same orientation on top of each other, with a thick film in between two adjacent offset stacks in order to accommodate the loop height of the wirebond on the topmost die in the lower offset stack; such an architecture may have a smaller footprint than an architecture with oppositely offset stacks, but may have a larger height. Another conventional single-side wirebond die stack architecture that does not include offset die stacks is a “film over wire” approach in which dies in the stack are aligned directly on top of each other, but adjacent dies are spaced apart by a thick film to accommodate the loop height of the wirebonds on each die. This architecture may require even greater heights than those relying on offset die stacks, and any advantage over offset die stacks may be lost when bond pads are disposed proximate to multiple sides of the dies (and thus wirebonds extend from multiple sides of the dies).

Moreover, as the thicknesses of the films between different dies in a conventional die stack increase (e.g., due to the need to accommodate loop heights), conventional approaches require the thicknesses of the dies themselves to increase. This arises due to the mismatch in the coefficients of thermal expansion (CTE) of the films and the dies; because the films and the dies will differently expand in response to heat, thicker dies are needed to “balance” thicker films to reduce the risk of cracking or delamination. Cracking and delamination become even more acute as more metal interconnect layers are included in a very thin die (as may be desirable, e.g., in a three-dimensional memory device in which different memory elements are disposed three-dimensionally in the die) because the proportion of the die that is silicon is relatively small and will likely not “balance” the expansion and contraction of the metal.

Various ones of the embodiments disclosed herein may reduce the height (i.e., in the z-direction) and/or footprint (i.e., in the x- and y-directions) of an IC package, and thus enable smaller and more powerful electronic devices than conventionally achievable. For example, various ones of the die stacks disclosed herein include pairs of dies whose contact faces “face” each other and can share a single wirebond connection to a package substrate; such die stacks may have a reduced z-height relative to previous die stacks by reducing the amount of inter-die film in the die stack. When a pair of dies shares a single wirebond connection, signal quality may be improved relative to embodiments in which the two dies are wirebonded to each other. Additionally, various ones of the die stacks disclosed herein may not require any offsetting between dies in the stack, reducing the footprint relative to offset die stacks. Further, in embodiments in which the two dies in a “facing” pair have mirror image structures, the thermal expansion and warping of one will be almost exactly countered by the thermal expansion of the other, balancing the die stress and reducing the risk of delamination.

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, a “high-k dielectric material” may refer to a material having a higher dielectric constant than silicon oxide.

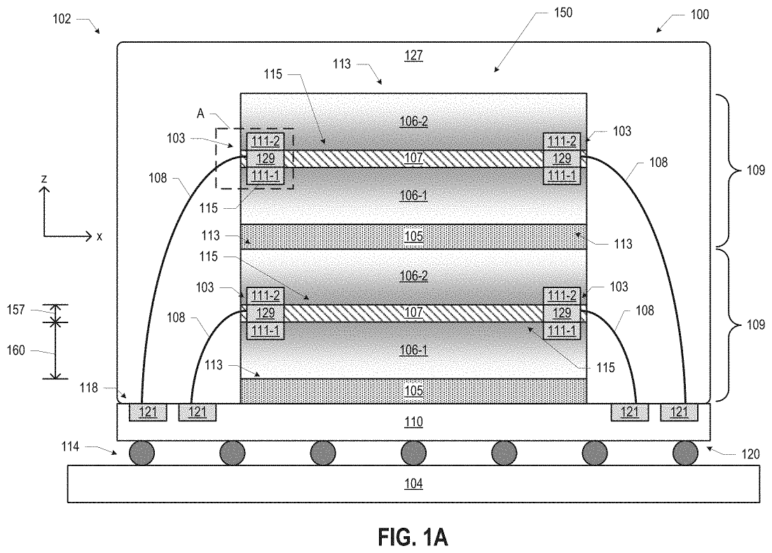

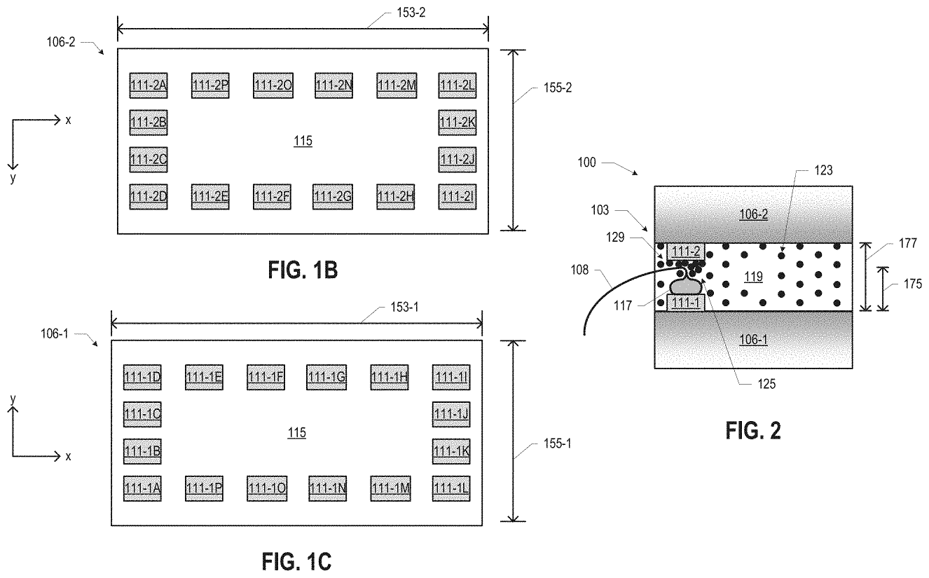

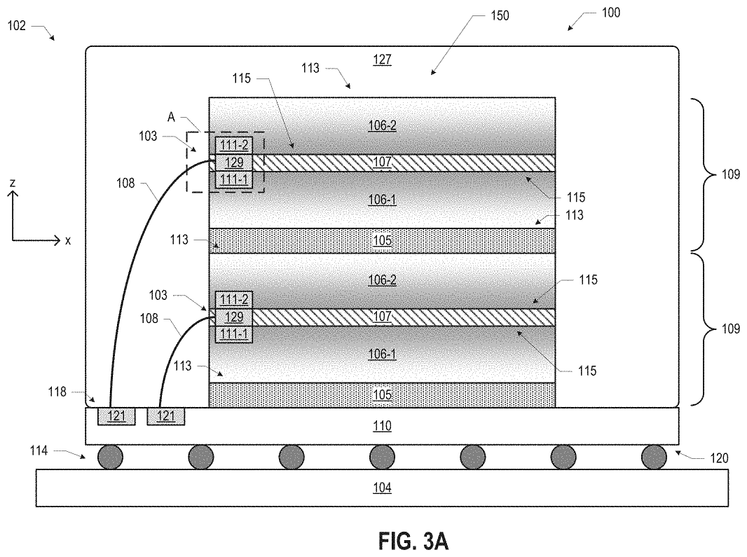

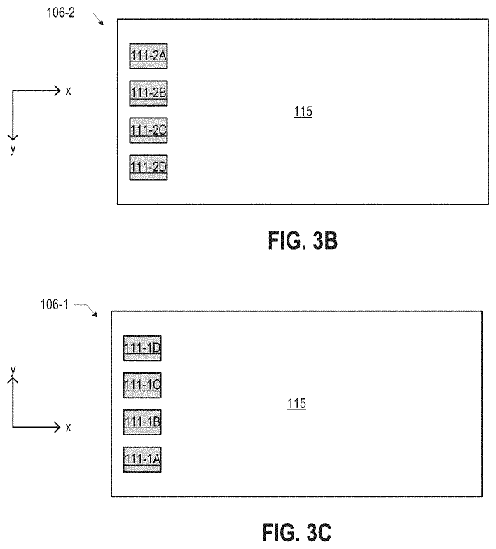

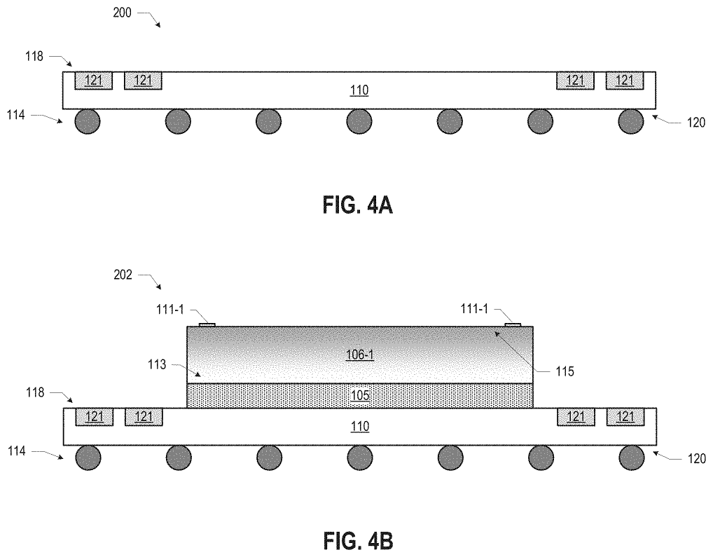

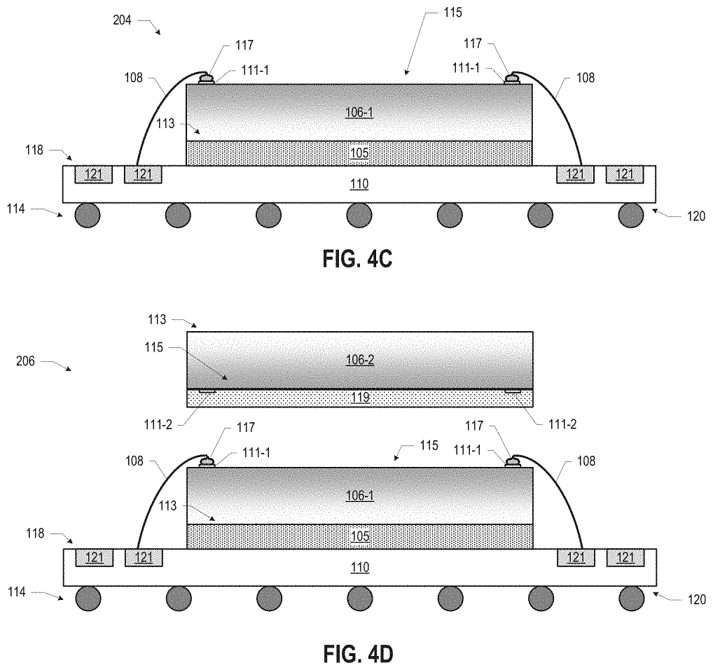

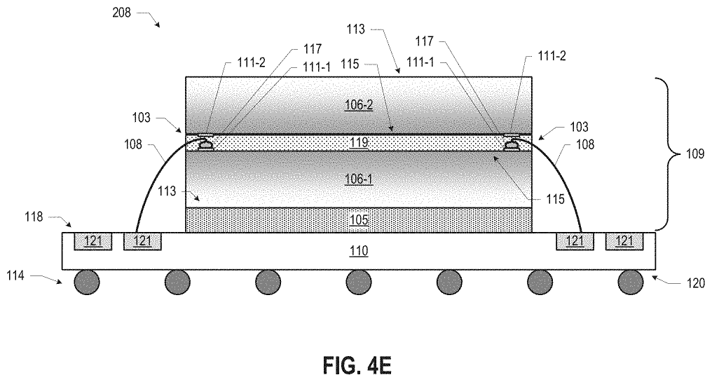

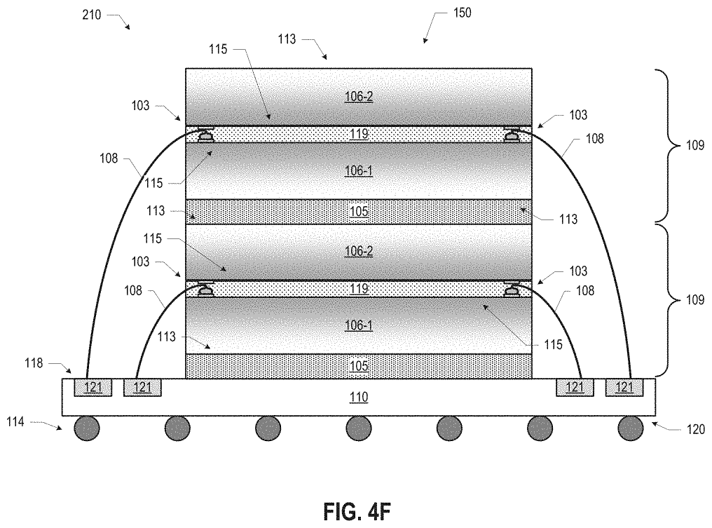

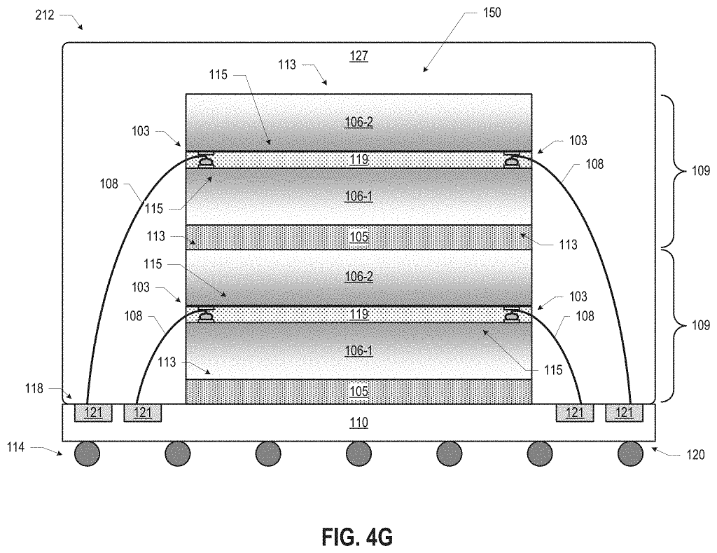

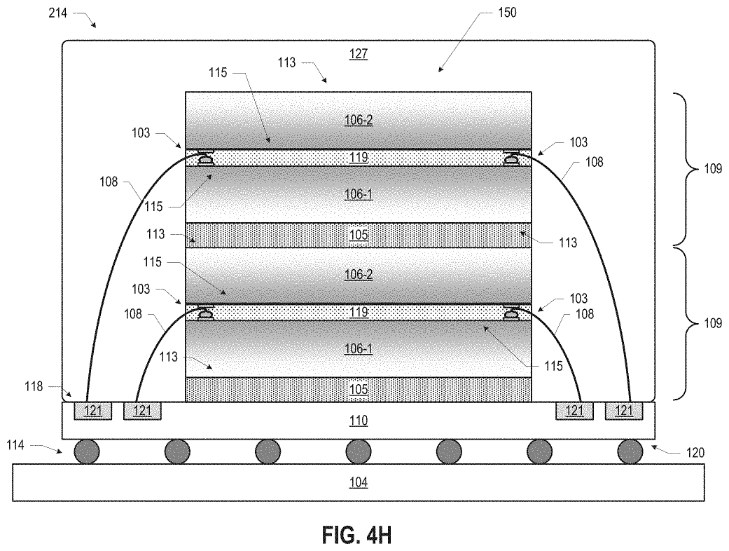

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. For ease of discussion, the term “FIG. 1” may be used to refer to the collection of drawings of FIGS. 1A-1C, the term “FIG. 3” may be used to refer to the collection of drawings of FIGS. 3A-3C, the term “FIG. 4” may be used to refer to the collection of drawings of FIGS. 4A-4H, and the term “FIG. 6” may be used to refer to the collection of drawings of FIGS. 6A-6B.

FIGS. 1A-1C are various views of an integrated circuit (IC) device 102 including an IC package 100 with a die stack 150, in accordance with some embodiments. In particular, FIG. 1A is a side cross-sectional view of an IC device 102 with a particular embodiment of a die stack 150, FIG. 1B is a “bottom” view of the contact face 115 of a die 106-2 in the die stack 150, and FIG. 1C is a “top” view of the contact face 115 of a die 106-1 in the die stack 150.

The IC package 100 may include a package substrate 110 and a die stack 150 disposed thereon. The die stack 150 may include multiple dies 106, with the dies 106 arranged in stacked die pairs 109. Each stacked die pair 109 may include a “lower” die 106-1 and an “upper” die 106-2. Although two stacked die pairs 109 are illustrated in FIG. 1A, a die stack 150 may include any number of dies 106 (e.g., any number of stacked die pairs 109). For example, in some embodiments, the die stack 150 may include eight or more dies 106 (e.g., arranged in four or more stacked die pairs 109). In some embodiments, the die stack 150 may include sixteen or more dies 106 (e.g., arranged in eight or more stacked die pairs 109). In some embodiments, the die stack 150 may include sixteen or more dies 106 (e.g., arranged in eight or more stacked die pairs 109).

The die 106-1 in a stacked die pair 109 may have a contact face 115 and an opposing face 113. One or more conductive contacts 111-1 may be disposed at the contact face 115 of a die 106-1. In some embodiments, no conductive contacts may be disposed at the opposing face 113 of the die 106-1, while in other embodiments, one or more conductive contacts may be disposed at the opposing face 113 (not shown). The die 106-1 in a stacked die pair 109 may be arranged in the die stack 150 so that its opposing face 113 is between its contact face 115 and the package substrate 110.

The die 106-2 in a stacked die pair 109 may also have a contact face 115 and an opposing face 113. One or more conductive contacts 111-2 may be disposed at the contact face 115 of a die 106-2. In some embodiments, no conductive contacts may be disposed at the opposing face 113 of the die 106-2, while in other embodiments, one or more conductive contacts may be disposed at the opposing face 113 (not shown). The die 106-2 and a stacked die pair 109 may be arranged in the die stack 150 so that its contact face 115 is between its opposing face 113 and the package substrate 110.

One or more of the conductive contacts 111-1 of the die 106-1 may be aligned with an associated one or more of the conductive contacts 111-2 of the die 106-2 in a stacked die pair 109 some of the conductive contacts 111-1 and the conductive contacts 111-2 are “facing” each other. Thus, each of the conductive contacts 111-1 at the contact face 115 of the die 106-1 may have an associated conductive contact 111-2 at the contact face 115 of the die 106-2. For example, FIG. 1B is a view of an example contact face 115 of a die 106-2, and FIG. 1C is a view of an example contact face 115 of a die 106-1; when the die 106-1 depicted in FIG. 1C and the die 106-2 depicted in FIG. 1B are stacked in a stacked die pair 109, the conductive contact 111-1X of the die 106-1 may be aligned with a corresponding conductive contact 111-2X of the die 106-2 (where X takes the values A, B, . . . , P). The arrangement of the conductive contacts 111-1 of the die 106-1 and the arrangement of the conductive contacts 111-2 of the die 106-2 may be mirror images in the sense that the dies 106-1 and 106-2 may be arranged with their contact faces 115 facing each other, and each conductive contact 111-1 is aligned with an associated conductive contact 111-2. In some embodiments, the structure of the dies 106-1 and 106-2 themselves may be mirror images in the sense that the structures within the die 106-1 (e.g., the conductive lines, vias, transistors, memory elements, passive devices, active devices, etc.) may be mirrored around the contact faces 115 by the same structures in the die 106-2. As noted above, a stacked die pair 109 with such mirroring may experience balanced stresses due to thermal expansion and contraction, and thus may be at lower risk for delamination during operation.

The conductive contacts 111 may take any suitable form. For example, in some embodiments, the conductive contacts 111 may be bond pads to which bondwires 108 may be coupled as part of a wirebonding process, as discussed below. In some embodiments, the conductive contacts 111 may be other conductive pads, conductive posts, or other conductive structures. The conductive contacts 111 may be surrounded by solder resist on the contact face 115, and may be recessed below, level with, or protrude from an outer surface of the solder resist.

In some embodiments, the contact face 115 of the die 106-1 and/or the contact face 115 of the die 106-2 may include one or more conductive contacts that don't have a “counterpart” on the other die in the stacked die pair 109; such conductive contacts are not illustrated in FIG. 1, and may not be present. For clarity of illustration, the remainder of the present disclosure may discuss a conductive contact 111-1 and its “associated” conductive contact 111-2; these conductive contacts 111-1 and 111-2 are aligned in a stacked die pair 109 and electrically coupled, as discussed below.

In a stacked die pair 109, a conductive material 129 may electrically couple the conductive contact 111-1 of the die 106-1 and its associated conductive contact 111-2 of the die 106-2. Although the “conductive material 129” may be referred to in the singular, the conductive material 129 may include one or more conductive materials. The conductive material 129 may take any suitable form, a number of which are described herein. For example, in some embodiments, the conductive material 129 may include a conductive adhesive that may mechanically and electrically couple the die 106-1 and the die 106-2 in a stacked die pair 109. In some embodiments, the conductive material 129 may include a solder that may mechanically and electrically couple the die 106-1 and the die 106-2 and a stacked die pair 109.

In some embodiments, the conductive material 129 may include an anisotropic conductive film. As used herein, an “anisotropic conductive film” may be a two-sided film that includes conductive materials dispersed in a non-conductive material. In some embodiments, an anisotropic conductive film may include microscopic conductive particles embedded in a binder thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold that is in turn coated with a polymer. In another example, the conductive particles may include nickel.

When an anisotropic conductive film is uncompressed, there may be no conductive pathway from one side of the film to the other. However, when the anisotropic conductive film is adequately compressed, the conductive materials near the region of compression may contact each other so as to form a conductive pathway from one side of the film to the other in the region of compression. When the conductive material 129 includes an anisotropic conductive film, the anisotropic conductive film may be compressed between the conductive contact 111-1 and its associated conductive contact 111-2, providing a conductive pathway between the conductive contacts 111-1 and 111-2. In some embodiments, this compression may be the result of one or both of the conductive contacts 111-1 and 111-2 taking the form of a post; when a post and a pad, or a post and a post, are brought together, the intervening anisotropic conductive film may be compressed. Other particular examples of embodiments in which the conductive material 129 includes an anisotropic conductive film are discussed below with reference to FIGS. 3 and 4.

A conductive contact 111-1, its associated conductive contact 111-2 in a stacked die pair 109, and the intervening conductive material 129 may be referred to herein as a die pair conductive structure 103. In some embodiments, a die pair conductive structure 103 may be electrically coupled to a conductive contact 121 at a first face 118 of the package substrate 110. For example, as illustrated in FIG. 1, each of the die pair conductive structures 103 may be electrically coupled to a conductive contact 121 by a bondwire 108. The bondwires 108 may be formed of any suitable material, such as copper, gold, or silver, and may have any suitable dimensions (e.g., a diameter between 15 microns and 30 microns, or between 20 microns and 25 microns). In some embodiments, the dies 106-1 and 106-2 may include memory devices, and the bondwires 108 may couple the associated conductive contacts 111-1 and 111-2 to a bus (not shown) that controls reading and writing from the memory devices.

In such embodiments, the bondwire 108 may be electrically coupled to its associated die pair conductive structure 103 in any suitable manner. For example, in some embodiments, the bondwire 108 may be bonded to the conductive contact 111-1 (e.g., using ball bonding, wedge bonding, or compliant bonding). The bondwire 108 may also be bonded to the associated conductive contact 121 (e.g., a bond finger or other bond pad). In such an embodiment, the conductive material 129 may include the wirebond bump that couples the bondwire 108 to the conductive contact 111-1 (formed during a ball-bonding operation) and any additional conductive material between the wirebond bump and the conductive contact 111-2 or between the conductive contact 111-1 and the conductive contact 111-2 (e.g., conductive adhesive, solder, anisotropic conductive film, etc.). In such an embodiment, the conductive contact 111-1 may be a bond pad, and the conductive contact 111-2 may take any suitable form (e.g., a bond pad).

For example, FIG. 2 is a cross-sectional side view of an example die pair conductive structure 103 that may be included in a die stack 150, in accordance with various embodiments. In particular, FIG. 3 represents a detailed view of an embodiment of the portion of the IC device 102 labeled “A” in FIG. 1A (and FIG. 3A, discussed below). In FIG. 3, the die pair conductive structure 103 includes a conductive contact 111-1 (e.g., a bond pad) on which a wirebond bump 117 is disposed. The bondwire 108 extends from the wirebond bump 117 (down to the package substrate 110, not shown in FIG. 3). An anisotropic conductive film 119 is disposed between the die 106-1 and the die 106-2; in some embodiments, the anisotropic conductive film 119 may extend through the entire area between the die 106-1 and the die 106-2 (e.g., the anisotropic conductive film 119 may provide the film 107). The anisotropic conductive film 119 may include particles or other small portions of a conductive material 123, and may be largely uncompressed in the areas between the dies 106-1 and 106-2 outside of the area between the conductive contacts 111-1 and 111-2. However, in the area between the conductive contacts 111-1 and 111-2, the conductive contacts 111-1 and 111-2 and the wirebond bump 117 may compress the thickness of the anisotropic conductive film 119 to at least a critical thickness of the anisotropic conductive film 119 that allows enough of the conductive material 123 to form a conductive pathway between the conductive contact 111-1 and the conductive contact 111-2 (indicating by the region 125 of the anisotropic conductive film 119 having a higher density of the conductive material 123). Thus, in the embodiment of FIG. 3, the conductive material 129 may include the wirebond bump 117 and the conductive material 123 of the anisotropic conductive film 119. The thickness 177 of the anisotropic conductive film 119 may be great enough to accommodate the wire bond bump 117 and bondwire 108, and thus may be greater than the loop height 175. For example, in some embodiments, the thickness 177 may be greater than 30 microns (e.g., greater than 40 microns, or between 30 and 60 microns). In some embodiments, the thickness 177 of the anisotropic conductive film 119 may be greater than the thickness 160 of the dies 106.

In any particular stacked die pair 109, multiple die pair conductive structures 103 may be electrically coupled to different ones of the conductive contacts 121 at the package substrate 110. Additionally, in embodiments in which the die stack 150 includes multiple stacked die pairs 109, multiple different ones of the stacked die pairs 109 in the die stack 150 may include one or more die pair conductive structures 103 electrically coupled to conductive contacts 121 at the package substrate 110.

In some embodiments, an adhesive may be disposed between the die 106-1 and the die 106-2 in a stacked die pair 109 to mechanically couple the die 106-1 and the die 106-2. For example, FIG. 1 illustrates a film 107 disposed between the dies 106-1 and 106-2 in each of the stacked die pairs 109. In some embodiments, the film 107 may be a die attach film. In some embodiments, the film 107 may be an anisotropic conductive film, and that anisotropic conductive film may extend between the conductive contacts 111-1 and the conductive contacts 111-2 to form part of the conductive material 129 of the die pair conductive structures 103, as discussed above and below.

In some embodiments, adjacent stacked die pairs 109 in a die stack 150 may be mechanically coupled together. For example, FIG. 1 illustrates a die attach film 105 disposed between the two stacked die pairs 109. In particular, a die attach film 105 may be disposed between the opposing face 113 of a die 106-2 in a “lower” stacked die pair 109, and the opposing face 113 of a die 106-1 in an adjacent “upper” stacked die pair 109. Additionally, a die attach film 105 may be disposed between the “bottom” stacked die pair 109 and the package substrate 110. In particular, the die attach film 105 may be disposed between the package substrate 110 and the opposing face 113 of a die 106-1 in the “bottommost” stacked die pair 109.

In some embodiments, a mold material 127 may be disposed around the die stack 150 on the package substrate 110. The mold material 127 may provide mechanical protection for the die stack 150 and the bondwires 108, and may provide a “flat” upper surface for marking and test of the IC package 100. The mold material 127 may be formed of any suitable material, such as a polymer compound, a poly-resin mold compound, an elastomer mold compound, or any other suitable material. Other examples of mold materials that may be included in the mold material 127 may include plastic materials, thermosetting polymers, silicon composites, glass, epoxy resins, or fiberglass epoxy resins. The mold material 127 may also include some filler material. For example, a mold material 127 may include an epoxy resin with tiny grains (e.g., on the order of a micrometer) of fused silica or amorphous silicon dioxide.

Although a single die stack 150 is illustrated in FIG. 1 as disposed on the package substrate 110, any number of electrical components (e.g., any number of die stacks 150, passive components, active components, etc.) may be secured to and/or in electrical contact with the package substrate 110. The package substrate 110 may have a second face 120 opposite to the first face 118. In some embodiments, one or more electrical components (e.g., dies) may be coupled to the second face 120 of the package substrate 110 (e.g., via wirebonds, solder bumps or balls, or other first level interconnects) (not shown). In some embodiments, the conductive contacts 121 may be surrounded by solder resist, as known in the art.

The dies 106 may have any suitable functionality, and may include passive devices (e.g., resistors, capacitors, and/or inductors), active devices (e.g., processing devices, memory, communications devices, and/or sensors), or any other computing components or circuitry. For example, in some embodiments, one or more of the dies 106 (e.g., all of the dies 106 in the die stack 150) may include memory devices, such as three-dimensional crosspoint or other memory architectures.

The dies 106 and the die stack 150 may have any suitable dimensions. For example, in some embodiments, the thickness 160 of a die 106 (e.g., a die 106-1 or a die 106-2) may be between 20 microns and 200 microns (e.g., between 20 microns and 100 microns, between 20 microns and 60 microns, between 50 microns and 60 microns, between 30 microns and 40 microns, or between 20 microns and 40 microns).

In some embodiments, the distance 157 between the contact face 115 of a die 106-1 and the contact face 115 of a die 106-2 in a stacked die pair 109 may be greater than the thickness 160. In some embodiments, the distance 157 may be between 30 microns and 60 microns (e.g., between 40 microns and 60 microns). In some embodiments, all of the dies 106 in a die stack 150 may have the same length 153, while in other embodiments, different ones of the dies 106 may have different lengths 153. Similarly, in some embodiments, all of the dies 106 in a die stack 150 may have the same width 155, while in other embodiments, different ones of the dies 106 may have different widths 155. In some embodiments, all of the dies 106 in a die stack 150 may have the same footprint (i.e., the same length 153 and the same width 155). In some embodiments, the dies 106-1 and 106-2 in a particular stacked die pair 109 may have the same footprint (i.e., the length 153-1 may be equal to the length 153-2, and the width 155-1 may be equal to the width 155-2), while in other embodiments, the dies 106-1 and 106-2 in a particular stacked die pair 109 may have different footprints.

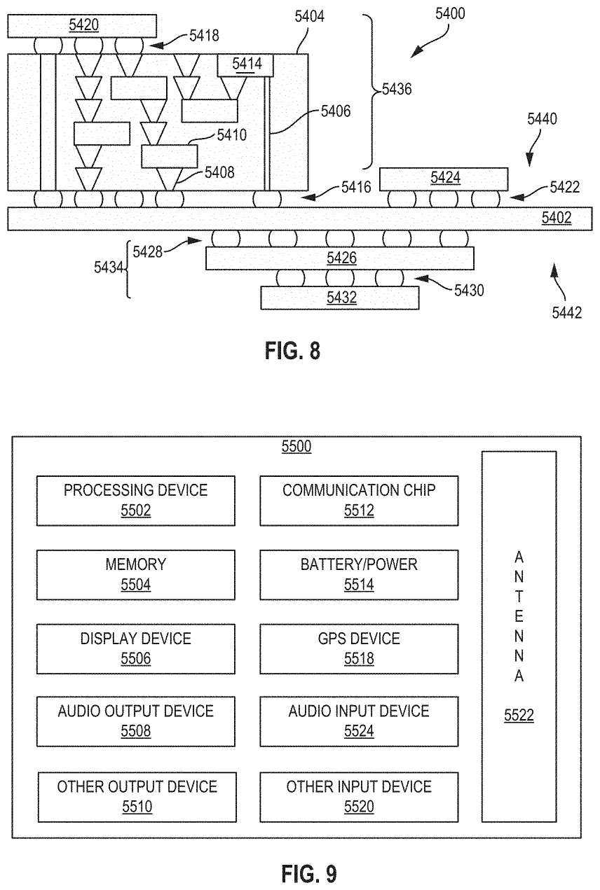

The package substrate 110 may be coupled to a circuit board 104 via second level interconnects 114 disposed at the second face 120 of the package substrate 110. In some embodiments, the second level interconnects 114 may include solder balls (as illustrated in FIG. 1) for a ball grid array (BGA) coupling; in other embodiments, the second level interconnects 114 may include solder paste contacts to provide land grid array (LGA) interconnects, or any other suitable interconnect. The circuit board 104 may include conductive pathways (not shown) that allow power, ground, and other electrical signals to move between the circuit board 104 and the IC package 100, as known in the art. Although FIG. 1 illustrates a single IC package 100 disposed on the circuit board 104, this is simply for ease of illustration and multiple IC packages may be disposed on the circuit board 104 (e.g., as discussed below with reference to the circuit board 5402 of the assembly 5400 of FIG. 8). In some embodiments, the circuit board 104 may be a printed circuit board (PCB) (e.g., a motherboard). In some embodiments, the circuit board 104 may be another IC package, and the IC device 102 may be a package-on-package structure. In some embodiments, the circuit board 104 may be an interposer, and the IC device 102 may be a package-on-interposer structure.

The package substrate 110 may include an insulating material and one or more conductive pathways through the insulating material, in accordance with various embodiments. In some embodiments, the insulating material may be provided by a single material, while in other embodiments, the insulating material may include different layers formed of different materials. For example, a “base” layer of insulating material may be provided by a glass fiber reinforced core, a rigid carrier, or a peelable core panel, for example, while additional layers of insulating material may be provided by an epoxy-based laminate. In some embodiments, the package substrate 110 may be an organic substrate. For example, in some embodiments, the insulating material of the package substrate 110 may be an organic material, such as an epoxy-based laminate. The insulating material may be, for example, a build-up film (e.g., Ajinomoto build-up film). The insulating material may include, for example, an epoxy with a phenolic hardener. The conductive pathways in the package substrate 110 may couple any of the dies 106 to the circuit board 104 (e.g., via the bondwires 108 and the second level interconnects 114), and/or may couple multiple ones of the dies 106 to each other (e.g., via the bondwires 108). Any suitable arrangement of conductive pathways in the package substrate 110 may couple the dies 106 and the circuit board 104, as desired.

The particular number and arrangement of conductive contacts 111 in FIGS. 1B and 1C is simply illustrative, and any number and arrangement of conductive contacts 111 may be used. For example, FIG. 3 illustrates an IC device 102 including an IC package 100 in which dies 106 in the die stack 150 are conductively coupled to conductive contacts 121 on the package substrate 110 at one side (e.g., one face joining the contact face 115 and the opposing face 113) of each of the dies 106. In particular, FIG. 3A is a side cross-sectional view of the IC device 102, FIG. 3B is a “bottom” view of the contact face 115 of a die 106-2 in the die stack 150 of FIG. 3A, and FIG. 3C is a “top” view of the contact face 115 of a die 106-1 in the die stack 150 of FIG. 3A. As shown in FIG. 3, the conductive contacts 111 on a die 106 may be grouped proximate to a single side of the die 106. Other than the locations of the conductive contacts 111 (and the associated conductive contacts 121), the IC device 102 of FIG. 3 may take any of the forms discussed herein with reference to FIG. 1.

Any suitable techniques may be used to manufacture the die stacks 150, IC packages 100, and IC devices 102 disclosed herein. For example, FIGS. 4A-4H are cross-sectional side views of various stages in the manufacture of the IC device 102 of FIG. 1 with the die pair conductive structures 103 of FIG. 3, in accordance with various embodiments. The operations discussed below with reference to FIGS. 4A-4G may be performed to manufacture an example of the IC package 100 of FIG. 1. Although FIGS. 4A-4H illustrate the manufacture of the particular IC device 102 illustrated in FIGS. 1 and 3, the techniques discussed below with reference to FIGS. 4A-4H may be used to manufacture any suitable ones of the die stacks 150, IC packages 100, and IC devices 102 disclosed herein.

FIG. 4A is a cross-sectional side view of an assembly 200 including a package substrate 110. The package substrate 110 may have one or more conductive contacts 121 disposed at a first face 118, and second level interconnects 114 disposed on the second face 120. The package substrate 110 of the assembly 200 may take any of the forms disclosed herein.

FIG. 4B is a cross-sectional side view of an assembly 202 subsequent to coupling a die 106-1 to the first face 118 of the package substrate 110 of the assembly 200 (FIG. 4A). The opposing face 113 of the die 106-1 may be coupled to the first face 118 of the package substrate 110 with a die attach film 105. The die 106-1 may include one or more conductive contacts 111-1 (e.g., bond pads) disposed at a contact face 115. In some embodiments, the die attach film 105 may be provided on the die 106-1 at the wafer level, and the die 106-1/die attach film 105 may together be brought in contact with the package substrate 110.

FIG. 4C is a cross-sectional side view of an assembly 204 subsequent to wirebonding the conductive contacts 111-1 of the die 106-1 to some of the conductive contacts 121 of the package substrate 110 of the assembly 202 (FIG. 4B). Wirebond bumps 117 may secure the bondwires 108 to the conductive contacts 111-1 such that the bondwires 108 extend from the wirebond bumps 117. Wirebond bumps may also be present at the conductive contacts 121, but are not shown for ease of illustration. Any desired wirebonding technique may be used to couple the conductive contacts 111-1 and the conductive contacts 121, such as any of the techniques discussed above.

FIG. 4D is a cross-sectional side view of an assembly 206 subsequent to bringing a die 106-2 and anisotropic conductive film 119 in proximity to the die 106-1 of the assembly 204 (FIG. 4C). In particular, the die 106-2 may have one or more conductive contacts 111-2 disposed at a contact face 115 of the die 106-2, and the anisotropic conductive film 119 may be disposed between the contact face 115 of the die 106-2 and the contact face 115 of the die 106-1. In some embodiments, the anisotropic conductive film 119 may be provided on the die 106-2 at the wafer level, and the die 106-2/anisotropic conductive film 119 may together be brought proximate to the die 106-1. The anisotropic conductive film 119 may extend over the conductive contacts 111-2.

FIG. 4E is a cross-sectional side view of an assembly 208 subsequent to bringing the die 106-2 and the anisotropic conductive film 119 of the assembly 206 (FIG. 4D) in contact with the contact face 115 of the die 106-1. This contact may include applying pressure to sandwich the anisotropic conductive film 119 between the contact faces 115, and the anisotropic film may be subsequently cured. As discussed above with reference to FIG. 3, the anisotropic conductive film 119 may be “squeezed” between the conductive contacts 111-2 and the associated wirebond bumps 117 and conductive contacts 111-1, forming a conductive pathway in the anisotropic conductive film 119 that bridges the conductive contacts 111-1 and their associated conductive contacts 111-2 (as well as the associated bondwires 108). The die 106-1 and the die 106-2 of the assembly 208 may provide a stacked die pair 109.

FIG. 4F is a cross-sectional side view of an assembly 210 subsequent to forming another stacked die pair 109 on top of the stacked die pair 109 of the assembly 208 (FIG. 4E). The additional stacked die pair 109 may be formed by repeating the operations discussed above with reference to FIGS. 4B-4E (e.g., attaching the “new” die 106-1 to the “old” die 106-2 with a die attach film 105, wire bonding the “new” die 106-1 to one or more conductive contacts on the package substrate 110, etc.). Although only two stacked die pairs 109 are illustrated in FIG. 4F, any suitable number of stacked die pairs 109 may be added by repeating the operations discussed above with reference to FIGS. 4B-4E. The stacked die pairs 109 of the assembly 210 may provide a die stack 150.

FIG. 4G is a cross-sectional side view of an assembly 212 subsequent to providing a mold material 127 on the package substrate 110 of the assembly 210 (FIG. 4F). The mold material 127 may surround the die stack 150 and may cover the bondwires 108. In some embodiments, no mold material 127 may be provided. The assembly 212 may take the form of the IC package 100 of FIGS. 1 and 3.

FIG. 4H is a cross-sectional side view of an assembly 214 subsequent to coupling the assembly 212 (FIG. 4G) to a circuit board 104. The assembly 212 may be secured to the circuit board 104 by the second level interconnects 114 (e.g., by a pick-and-place operation combined with solder reflow). The assembly 214 may take the form of the IC device 100 of FIGS. 1 and 3.

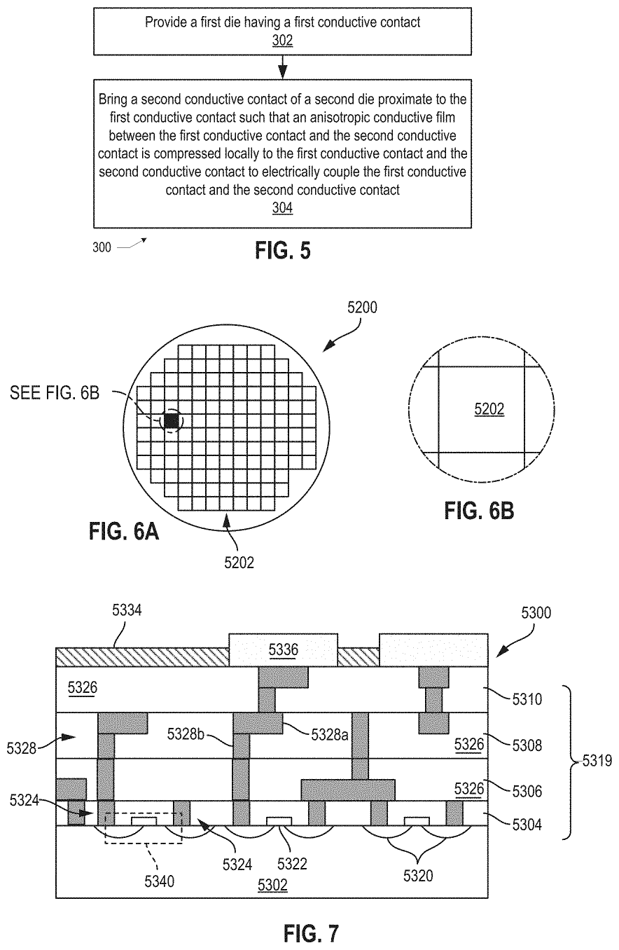

FIG. 5 is a flow diagram of an example method 300 of manufacturing a die stack, in accordance with various embodiments. Although the various operations discussed with reference to the method 300 are shown in a particular order and once each, the operations may be performed in any suitable order (e.g., in any combination of parallel or series performance), and may be repeated or omitted as suitable. Additionally, although various operations of the method 300 may be illustrated with reference to particular embodiments of the die stacks 150 disclosed herein, these are simply examples, and the method 300 may be used to form any suitable die stack.

At 302, a first die having a first conductive contact may be provided. For example, the die 106-1, having one or more conductive contacts 111-1 disposed at a contact face 115, may be provided.

At 304, a second conductive contact of a second die may be brought proximate to the first conductive contact of the first die such that an anisotropic conductive film between the first conductive contact and the second conductive contact is compressed locally to the first conductive contact and the second conductive contact to electrically couple the first conductive contact and the second conductive contact. In some embodiments, this compression may be caused by a protruding first conductive contact (e.g., a post), a protruding feature on the first conductive contact (e.g., a wirebond bump or solder bump), a protruding second conductive contact (e.g., a post), and/or a protruding feature on the second conductive contact (e.g., a wirebond bump or solder bump). For example, a conductive contact 111-2 on a contact face 115 of a die 106-2 may be brought proximate to the conductive contact 111-1 on the contact face 115 of the die 106-1 such that an anisotropic conductive film 119 between the conductive contacts 111-1 and 111-2 is compressed locally (e.g., by an intervening wirebond bump 117) to electrically couple the conductive contacts 111-1 and 111-2.

The die stacks 150 and/or the IC packages 100 disclosed herein may include, or be included in, any suitable electronic device. FIGS. 6-9 illustrate various examples of apparatuses that may be included in, or that may include, one or more of any of the die stacks 150 and/or the IC packages 100 disclosed herein.

FIGS. 6A-6B are top views of a wafer 5200 and dies 5202 that may be included in any of the die stacks 150 and/or the IC packages 100 disclosed herein. The wafer 5200 may be composed of semiconductor material and may include one or more dies 5202 having IC elements formed on a surface of the wafer 5200. Each of the dies 5202 may be a repeating unit of a semiconductor product that includes any suitable IC. After the fabrication of the semiconductor product is complete, the wafer 5200 may undergo a singulation process in which each of the dies 5202 is separated from one another to provide discrete “chips” of the semiconductor product. The die 5202 may include one or more transistors (e.g., some of the transistors 5340 of FIG. 7, discussed below) and/or supporting circuitry to route electrical signals to the transistors, as well as any other IC components. In some embodiments, the wafer 5200 or the die 5202 may include a memory device (e.g., a static random access memory (SRAM) device), a logic device (e.g., AND, OR, NAND, or NOR gate), or any other suitable circuit element. Multiple ones of these devices may be combined on a single die 5202. For example, a memory array formed by multiple memory devices may be formed on a same die 5202 as a processing device (e.g., the processing device 5502 of FIG. 9) or other logic that is configured to store information in the memory devices or execute instructions stored in the memory array. Any of the dies 5202 may provide any of the dies 106 discussed herein, and may be included in a die stack 150 and/or IC package 100.

FIG. 7 is a cross-sectional side view of an IC device 5300 that may be part of any of the dies 106 disclosed herein (e.g., as part of a die stack 150 and/or IC package 100). The IC device 5300 may be formed on a substrate 5302 (e.g., the wafer 5200 of FIG. 6A) and may be included in a die (e.g., the die 5202 of FIG. 6B). The substrate 5302 may be a semiconductor substrate composed of semiconductor material systems including, for example, N-type or P-type materials systems. The substrate 5302 may include, for example, a crystalline substrate formed using a bulk silicon or a silicon-on-insulator substructure. In some embodiments, the substrate 5302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 5302. Although a few examples of materials from which the substrate 5302 may be formed are described here, any material that may serve as a foundation for an IC device 5300 may be used. The substrate 5302 may be part of a singulated die (e.g., the dies 5202 of FIG. 6B) or a wafer (e.g., the wafer 5200 of FIG. 6A).

The IC device 5300 may include one or more device layers 5304 disposed on the substrate 5302. The device layer 5304 may include features of one or more transistors 5340 (e.g., metal oxide semiconductor field-effect transistors (MOSFETs)) formed on the substrate 5302. The device layer 5304 may include, for example, one or more source and/or drain (S/D) regions 5320, a gate 5322 to control current flow in the transistors 5340 between the S/D regions 5320, and one or more S/D contacts 5324 to route electrical signals to/from the S/D regions 5320. The transistors 5340 may include additional features not depicted for the sake of clarity, such as device isolation regions, gate contacts, and the like. The transistors 5340 are not limited to the type and configuration depicted in FIG. 7 and may include a wide variety of other types and configurations such as, for example, planar transistors, nonplanar transistors, or a combination of both. Nonplanar transistors may include FinFET transistors, such as double-gate transistors or tri-gate transistors, and wraparound or all-around gate transistors, such as nanoribbon and nanowire transistors.

Each transistor 5340 may include a gate 5322 formed of at least two layers, a gate dielectric layer and a gate electrode layer. The gate dielectric layer may include one layer or a stack of layers. The one or more layers may include silicon oxide, silicon dioxide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer may be formed on the gate dielectric layer and may include at least one P-type work-function metal or N-type work-function metal, depending on whether the transistor 5340 is to be a PMOS or an NMOS transistor. In some implementations, the gate electrode layer may consist of a stack of two or more metal layers, where one or more metal layers are work-function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, when viewed as a cross section of the transistor 5340 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 5320 may be formed within the substrate 5302 adjacent to the gate 5322 of each transistor 5340. The S/D regions 5320 may be formed using either an implantation/diffusion process or an etching/deposition process, for example. In the former process, dopants such as boron, aluminum, antimony, phosphorous, or arsenic may be ion-implanted into the substrate 5302 to form the S/D regions 5320. An annealing process that activates the dopants and causes them to diffuse farther into the substrate 5302 may follow the ion-implantation process. In the latter process, the substrate 5302 may first be etched to form recesses at the locations of the S/D regions 5320. An epitaxial deposition process may then be carried out to fill the recesses with material that is used to fabricate the S/D regions 5320. In some implementations, the S/D regions 5320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 5320 may be formed using one or more alternate semiconductor materials such as germanium or a group III-V material or alloy. In further embodiments, one or more layers of metal and/or metal alloys may be used to form the S/D regions 5320.

Electrical signals, such as power and/or input/output (I/O) signals, may be routed to and/or from the transistors 5340 of the device layer 5304 through one or more interconnect layers disposed on the device layer 5304 (illustrated in FIG. 7 as interconnect layers 5306-5310). For example, electrically conductive features of the device layer 5304 (e.g., the gate 5322 and the S/D contacts 5324) may be electrically coupled with the interconnect structures 5328 of the interconnect layers 5306-5310. The one or more interconnect layers 5306-5310 may form an interlayer dielectric (ILD) stack 5319 of the IC device 5300.

The interconnect structures 5328 may be arranged within the interconnect layers 5306-5310 to route electrical signals according to a wide variety of designs (in particular, the arrangement is not limited to the particular configuration of interconnect structures 5328 depicted in FIG. 7). Although a particular number of interconnect layers 5306-5310 is depicted in FIG. 7, embodiments of the present disclosure include IC devices having more or fewer interconnect layers than depicted.

In some embodiments, the interconnect structures 5328 may include trench structures 5328a (sometimes referred to as “lines”) and/or via structures 5328b (sometimes referred to as “holes”) filled with an electrically conductive material such as a metal. The trench structures 5328a may be arranged to route electrical signals in a direction of a plane that is substantially parallel with a surface of the substrate 5302 upon which the device layer 5304 is formed. For example, the trench structures 5328a may route electrical signals in a direction in and out of the page from the perspective of FIG. 7. The via structures 5328b may be arranged to route electrical signals in a direction of a plane that is substantially perpendicular to the surface of the substrate 5302 upon which the device layer 5304 is formed. In some embodiments, the via structures 5328b may electrically couple trench structures 5328a of different interconnect layers 5306-5310 together.

The interconnect layers 5306-5310 may include a dielectric material 5326 disposed between the interconnect structures 5328, as shown in FIG. 7. The dielectric material 5326 may include any suitable interlayer dielectric (ILD), such as an oxide (e.g., silicon oxide or aluminum oxide), a nitride (e.g., silicon nitride), a carbide (e.g., silicon carbide), a carbonitride (e.g., silicon carbon nitride), an oxynitride (e.g., silicon oxynitride), or any combination thereof. In some embodiments, the dielectric material 5326 disposed between the interconnect structures 5328 in different ones of the interconnect layers 5306-5310 may have different compositions; in other embodiments, the composition of the dielectric material 5326 between different interconnect layers 5306-5310 may be the same.

A first interconnect layer 5306 (referred to as Metal 1 or “M1”) may be formed directly on the device layer 5304. In some embodiments, the first interconnect layer 5306 may include trench structures 5328a and/or via structures 5328b, as shown. The trench structures 5328a of the first interconnect layer 5306 may be coupled with contacts (e.g., the S/D contacts 5324) of the device layer 5304.

A second interconnect layer 5308 (referred to as Metal 2 or “M2”) may be formed directly on the first interconnect layer 5306. In some embodiments, the second interconnect layer 5308 may include via structures 5328b to couple the trench structures 5328a of the second interconnect layer 5308 with the trench structures 5328a of the first interconnect layer 5306. Although the trench structures 5328a and the via structures 5328b are structurally delineated with a line within each interconnect layer (e.g., within the second interconnect layer 5308) for the sake of clarity, the trench structures 5328a and the via structures 5328b may be structurally and/or materially contiguous (e.g., simultaneously filled during a dual-damascene process) in some embodiments.

A third interconnect layer 5310 (referred to as Metal 3 or “M3”) (and additional interconnect layers, as desired) may be formed in succession on the second interconnect layer 5308 according to similar techniques and configurations described in connection with the second interconnect layer 5308 or the first interconnect layer 5306.

The IC device 5300 may include a solder resist material 5334 (e.g., polyimide or similar material) and one or more bond pads 5336 formed on the interconnect layers 5306-5310. The bond pads 5336 may be the conductive contacts 111, for example. The bond pads 5336 may be electrically coupled with the interconnect structures 5328 and configured to route the electrical signals of the transistor(s) 5340 to other external devices. For example, wirebonds may be formed on the one or more bond pads 5336 to mechanically and/or electrically couple a chip including the IC device 5300 with another component (e.g., a package substrate). For example, a bondwire 108 may couple a bond pad 5336 to the package substrate 110. The IC device 5300 may have other alternative configurations to route the electrical signals from the interconnect layers 5306-5310 than depicted in other embodiments. For example, the bond pads 5336 may be replaced by or may further include other analogous features (e.g., posts) that route the electrical signals to external components.

FIG. 8 is a cross-sectional side view of an IC device assembly 5400 that may include any of the die stacks 150 and/or IC packages 100 disclosed herein. The IC device assembly 5400 includes a number of components disposed on a circuit board 5402 (which may be, e.g., the circuit board 104). The IC device assembly 5400 may include components disposed on a first face 5440 of the circuit board 5402 and an opposing second face 5442 of the circuit board 5402; generally, components may be disposed on one or both faces 5440 and 5442.

In some embodiments, the circuit board 5402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 5402. In other embodiments, the circuit board 5402 may be a non-PCB substrate.

The IC device assembly 5400 illustrated in FIG. 8 includes a package-on-interposer structure 5436 coupled to the first face 5440 of the circuit board 5402 by coupling components 5416. The coupling components 5416 may electrically and mechanically couple the package-on-interposer structure 5436 to the circuit board 5402, and may include solder balls (as shown in FIG. 8), male and female portions of a socket, an adhesive, an underfill material, and/or any other suitable electrical and/or mechanical coupling structure.

The package-on-interposer structure 5436 may include an IC package 5420 coupled to an interposer 5404 by coupling components 5418. The coupling components 5418 may take any suitable form for the application, such as the forms discussed above with reference to the coupling components 5416. For example, the coupling components 5418 may be the second level interconnects 114. Although a single IC package 5420 is shown in FIG. 8, multiple IC packages may be coupled to the interposer 5404; indeed, additional interposers may be coupled to the interposer 5404. The interposer 5404 may provide an intervening substrate used to bridge the circuit board 5402 and the IC package 5420. The IC package 5420 may be or include, for example, a die (the die 5202 of FIG. 68), an IC device (e.g., the IC device 5300 of FIG. 7), or any other suitable component. In particular, the IC package 5420 may take the form of any of the embodiments of the IC packages 100 disclosed herein. Generally, the interposer 5404 may spread a connection to a wider pitch or reroute a connection to a different connection. For example, the interposer 5404 may couple the IC package 5420 (e.g., a die) to a ball grid array (BGA) of the coupling components 5416 for coupling to the circuit board 5402. In the embodiment illustrated in FIG. 8, the IC package 5420 and the circuit board 5402 are attached to opposing sides of the interposer 5404; in other embodiments, the IC package 5420 and the circuit board 5402 may be attached to a same side of the interposer 5404. In some embodiments, three or more components may be interconnected by way of the interposer 5404.

The interposer 5404 may be formed of an epoxy resin, a fiberglass-reinforced epoxy resin, a ceramic material, or a polymer material such as polyimide. In some embodiments, the interposer 5404 may be formed of alternate rigid or flexible materials that may include the same materials described above for use in a semiconductor substrate, such as silicon, germanium, and other group III-V and group IV materials. The interposer 5404 may include metal interconnects 5408 and vias 5410, including but not limited to through-silicon vias (TSVs) 5406. The interposer 5404 may further include embedded devices 5414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 5404. The package-on-interposer structure 5436 may take the form of any of the package-on-interposer structures known in the art.

The IC device assembly 5400 may include an IC package 5424 coupled to the first face 5440 of the circuit board 5402 by coupling components 5422. The coupling components 5422 may take the form of any of the embodiments discussed above with reference to the coupling components 5416, and the IC package 5424 may take the form of any of the embodiments discussed above with reference to the IC package 5420. In particular, the IC package 5424 may take the form of any of the embodiments of the IC packages 100 disclosed herein, or may otherwise include any of the die stacks 150 disclosed herein.

The IC device assembly 5400 illustrated in FIG. 8 includes a package-on-package structure 5434 coupled to the second face 5442 of the circuit board 5402 by coupling components 5428. The package-on-package structure 5434 may include an IC package 5426 and an IC package 5432 coupled together by coupling components 5430 such that the IC package 5426 is disposed between the circuit board 5402 and the IC package 5432. The coupling components 5428 and 5430 may take the form of any of the embodiments of the coupling components 5416 discussed above, and the IC packages 5426 and 5432 may take the form of any of the embodiments of the IC package 5420 discussed above. In particular, the IC packages 5426 and 5432 may take the form of any of the embodiments of the IC packages 100 disclosed herein, or may otherwise include any of the die stacks 150 disclosed herein.

FIG. 9 is a block diagram of an example computing device 5500 that may include one or more of the package substrates 110 disclosed herein. For example, any suitable ones of the components of the computing device 5500 may include, or be included in, a die stack 150 and/or an IC package 100, in accordance with any of the embodiments disclosed herein. A number of components are illustrated in FIG. 9 as included in the computing device 5500, but any one or more of these components may be omitted or duplicated, as suitable for the application. In some embodiments, some or all of the components included in the computing device 5500 may be attached to one or more motherboards. In some embodiments, some or all of these components are fabricated onto a single system-on-a-chip (SoC) die.

Additionally, in various embodiments, the computing device 5500 may not include one or more of the components illustrated in FIG. 9, but the computing device 5500 may include interface circuitry for coupling to the one or more components. For example, the computing device 5500 may not include a display device 5506, but may include display device interface circuitry (e.g., a connector and driver circuitry) to which a display device 5506 may be coupled. In another set of examples, the computing device 5500 may not include an audio input device 5524 or an audio output device 5508, but may include audio input or output device interface circuitry (e.g., connectors and supporting circuitry) to which an audio input device 5524 or audio output device 5508 may be coupled.

The computing device 5500 may include a processing device 5502 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 5502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 5500 may include a memory 5504, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 5504 may include memory that shares a die with the processing device 5502. This memory may be used as cache memory and may include embedded dynamic random access memory (eDRAM) or spin transfer torque magnetic random-access memory (STT-MRAM). In some embodiments, the processing device 5502 and/or the memory 5504 may be included in a die stack 150 and/or an IC package 100 (e.g., the same die stack 150/IC package 100 or different die stacks 150/IC packages 100).

In some embodiments, the computing device 5500 may include a communication chip 5512 (e.g., one or more communication chips). For example, the communication chip 5512 may be configured for managing wireless communications for the transfer of data to and from the computing device 5500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. In some embodiments, the communication chip 5512 may be included in an IC package 100.

The communication chip 5512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 5512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 5512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 5512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 5512 may operate in accordance with other wireless protocols in other embodiments. The computing device 5500 may include an antenna 5522 to facilitate wireless communications and/or to receive other wireless communications (such as AM or FM radio transmissions).

In some embodiments, the communication chip 5512 may manage wired communications, such as electrical, optical, or any other suitable communication protocols (e.g., the Ethernet). As noted above, the communication chip 5512 may include multiple communication chips. For instance, a first communication chip 5512 may be dedicated to shorter-range wireless communications such as Wi-Fi or Bluetooth, and a second communication chip 5512 may be dedicated to longer-range wireless communications such as GPS, EDGE, GPRS, CDMA, WiMAX, LTE, EV-DO, or others. In some embodiments, a first communication chip 5512 may be dedicated to wireless communications, and a second communication chip 5512 may be dedicated to wired communications.

The computing device 5500 may include battery/power circuitry 5514. The battery/power circuitry 5514 may include one or more energy storage devices (e.g., batteries or capacitors) and/or circuitry for coupling components of the computing device 5500 to an energy source separate from the computing device 5500 (e.g., AC line power).

The computing device 5500 may include a display device 5506 (or corresponding interface circuitry, as discussed above). The display device 5506 may include any visual indicators, such as a heads-up display, a computer monitor, a projector, a touchscreen display, a liquid crystal display (LCD), a light-emitting diode display, or a flat panel display, for example.

The computing device 5500 may include an audio output device 5508 (or corresponding interface circuitry, as discussed above). The audio output device 5508 may include any device that generates an audible indicator, such as speakers, headsets, or earbuds, for example.

The computing device 5500 may include an audio input device 5524 (or corresponding interface circuitry, as discussed above). The audio input device 5524 may include any device that generates a signal representative of a sound, such as microphones, microphone arrays, or digital instruments (e.g., instruments having a musical instrument digital interface (MIDI) output).

The computing device 5500 may include a global positioning system (GPS) device 5518 (or corresponding interface circuitry, as discussed above). The GPS device 5518 may be in communication with a satellite-based system and may receive a location of the computing device 5500, as known in the art.

The computing device 5500 may include an other output device 5510 (or corresponding interface circuitry, as discussed above). Examples of the other output device 5510 may include an audio codec, a video codec, a printer, a wired or wireless transmitter for providing information to other devices, or an additional storage device.

The computing device 5500 may include an other input device 5520 (or corresponding interface circuitry, as discussed above). Examples of the other input device 5520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 5500 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 5500 may be any other electronic device that processes data.

The following paragraphs provide various examples of the embodiments disclosed herein.

Example 1 is an integrated circuit (IC) package, including: a package substrate having a substrate conductive contact; a first die coupled to the package substrate, wherein the first die has a first face and an opposing second face, the second face of the first die is between the first face of the first die and the package substrate, and the first die has a first conductive contact at the first face of the first die; a second die coupled to the first die, wherein the second die has a first face and an opposing second face, the first face of the second die is between the first die and the second face of the second die, and the second die has a second conductive contact at the first face of the second die; and a bondwire between the first conductive contact and the substrate conductive contact, wherein the bondwire is also in electrical contact with the second conductive contact.

Example 2 may include the subject matter of Example 1, and may further include conductive material between the first die and the second die to electrically couple the first conductive contact and the second conductive contact.

Example 3 may include the subject matter of Example 2, and may further specify that the conductive material includes an anisotropic conductive film.

Example 4 may include the subject matter of any of Examples 2-3, and may further specify that the conductive material includes a wire bond bump.

Example 5 may include the subject matter of Example 4, and may further specify that the conductive material includes an anisotropic conductive film.

Example 6 may include the subject matter of any of Examples 2-5, and may further specify that the conductive material includes a conductive adhesive.

Example 7 may include the subject matter of any of Examples 1-6, and may further specify that the first conductive contact is one of a plurality of first conductive contacts at the first face of the first die, the substrate conductive contact is one of a plurality of substrate conductive contacts at the package substrate, and individual ones of the first conductive contacts are wirebonded to associated individual ones of the substrate conductive contacts.

Example 8 may include the subject matter of Example 7, and may further specify that the second conductive contact is one of a plurality of second conductive contacts at the first face of the second die, and individual ones of the first conductive contacts are electrically coupled to associated individual ones of the second conductive contacts.

Example 9 may include the subject matter of any of Examples 7-8, and may further specify that the first die includes a plurality of sides extending between the first face and the second face, and the plurality of first conductive contacts are disposed proximate to a single one of the sides.

Example 10 may include the subject matter of any of Examples 7-8, and may further specify that the first die includes a plurality of sides extending between the first face and the second face, and the plurality of first conductive contacts are disposed proximate to multiple ones of the sides.

Example 11 may include the subject matter of any of Examples 1-10, and may further specify that the first conductive contact is one of a plurality of first conductive contacts at the first face of the first die, the second conductive contact is one of a plurality of second conductive contacts at the first face of the second die, and individual ones of the first conductive contacts are electrically coupled to associated individual ones of the second conductive contacts.

Example 12 may include the subject matter of any of Examples 1-11, and may further specify that the first die and the second die have mirror image structures.

Example 13 may include the subject matter of any of Examples 1-12, and may further specify that a die attach film is between the first die and the package substrate.

Example 14 may include the subject matter of any of Examples 1-13, and may further specify that the first die and the second die include memory devices.

Example 15 may include the subject matter of any of Examples 1-14, and may further specify that the first die and the second die each have a thickness less than 60 microns.

Example 16 may include the subject matter of any of Examples 1-15, and may further specify that the first die and the second die are part of a die stack that includes at least 8 dies.

Example 17 may include the subject matter of Example 16, and may further specify that the die stack includes at least 16 dies.

Example 18 may include the subject matter of any of Examples 16-17, and may further specify that the die stack includes at least 32 dies.

Example 19 may include the subject matter of any of Examples 1-18, and may further specify that the bondwire is a first bondwire, the substrate conductive contact is a first substrate conductive contact, the package substrate has a second substrate conductive contact, and the IC package further includes: a third die coupled to the second die, wherein the third die has a first face and an opposing second face, the second face of the third die is between the first face of the first die and the second die, and the third die has a third conductive contact at the first face of the third die; a fourth die coupled to the third die, wherein the fourth die has a first face and an opposing second face, the first face of the fourth die is between the third die and the second face of the fourth die, and the fourth die has a fourth conductive contact at the first face of the fourth die; and a second bondwire between the third conductive contact and the second substrate conductive contact, wherein the bondwire is also in electrical contact with the fourth conductive contact.

Example 20 may include the subject matter of Example 19, and may further include conductive material between the third die and the fourth die to electrically couple the third conductive contact and the fourth conductive contact.

Example 21 may include the subject matter of Example 20, and may further specify that the conductive material between the third die and the fourth die includes an anisotropic conductive film.

Example 22 may include the subject matter of any of Examples 20-21, and may further specify that the conductive material between the third die and the fourth die includes a wire bond bump.

Example 23 may include the subject matter of Example 22, and may further specify that the conductive material between the third die and the fourth die includes an anisotropic conductive film.

Example 24 may include the subject matter of any of Examples 20-23, and may further specify that the conductive material between the third die and the fourth die includes a conductive adhesive.

Example 25 may include the subject matter of any of Examples 1-24, and may further specify that a lateral extent of the first die is the same as a lateral extent of the second die.

Example 26 may include the subject matter of any of Examples 1-25, and may further specify that the first die is not laterally offset from the second die.

Example 27 may include the subject matter of any of Examples 1-26, and may further include a film between the first die and the second die, wherein the film has a thickness less than a thickness of the first die.

Example 28 is a computing device, including: a circuit board; and an integrated circuit (IC) package on the circuit board, wherein the IC package includes a package substrate with a substrate conductive contact, the IC package includes a plurality of pairs of dies, individual ones of the pairs of dies include a first die with a first face and an opposing second face and a second die with a first face and an opposing second face, a first conductive contact is at the first face of individual first dies, a second conductive contact is at the first face of individual second dies, the first face of a first die in a pair is disposed between the second face of the first die and the first face of the second die, the first face of a second die in a pair is disposed between the first face of the first die and the second face of the second die, the first conductive contact and the second conductive contact are electrically coupled to a bondwire, and the bondwire is attached to the substrate conductive contact.

Example 29 may include the subject matter of Example 28, and may further specify that the IC package includes at least 8 pairs of dies.

Example 30 may include the subject matter of any of Examples 28-29, and may further specify that the IC package is coupled to the circuit board with second level interconnects.

Example 31 may include the subject matter of any of Examples 28-30, and may further specify that at least some of the dies in the plurality of pairs of dies include memory devices.

Example 32 may include the subject matter of Example 31, and may further specify that the memory devices are three-dimensional memory devices.

Example 33 may include the subject matter of any of Examples 28-32, and may further specify that the bondwire is wirebonded to the first conductive contact.

Example 34 may include the subject matter of any of Examples 28-33, and may further specify that the IC package includes an anisotropic conductive film between the first face of the first die and the first face of the second die in a pair of dies.

Example 35 may include the subject matter of any of Examples 28-34, and may further specify that the IC package includes a film between the first die and the second die in a pair of dies, and the film has a thickness greater than 40 microns.

Example 36 may include the subject matter of Example 35, and may further specify that the thickness of the film is greater than a thickness of the first die.

Example 37 is a method of manufacturing an integrated circuit (IC) package, including: providing a first die on a package substrate, wherein the first die has a first face and an opposing second face, the second face of the first die is between the first face of the first die and the package substrate, and a first conductive contact is at the first face of the first die; wirebonding the first conductive contact to a substrate conductive contact on the package substrate; and coupling a second die to the first die, wherein the second die has a first face and an opposing second face, the first face of the second die is between the first face of the first die and the second face of the second die, a second conductive contact is at the first face of the second die, and coupling the second die to the first die includes electrically coupling the first conductive contact to the second conductive contact.

Example 38 may include the subject matter of Example 37, and may further specify that providing the first die on the package substrate includes coupling the first die to the package substrate with a die attach film.

Example 39 may include the subject matter of any of Examples 37-38, and may further specify that an anisotropic conductive film is between the first face of the first die and the first face of the second die, and electrically coupling the first conductive contact to the second conductive contact includes bringing the first face of the first die proximate to the first face of the second die to compress the portion of the anisotropic conductive film between the first conductive contact and the second conductive contact.

Example 40 may include the subject matter of any of Examples 37-39, and may further specify that electrically coupling the first conductive contact to the second conductive contact includes providing a conductive adhesive on a wirebond bump on the first conductive contact and bringing the second conductive contact into contact with the conductive adhesive.

Example 41 may include the subject matter of any of Examples 37-40, and may further specify that the substrate conductive contact is a first substrate conductive contact, and the method further includes: coupling a third die to the second die, wherein the third die has a first face and an opposing second face, the second face of the third die is between the second die and the first face of the third die, and a third conductive contact is at the first face of the third die; wirebonding the third conductive contact to a second substrate conductive contact on the package substrate; and coupling a fourth die to the third die, wherein the fourth die has a first face and an opposing second face, the first face of the fourth die is between the first face of the third die and the second face of the fourth die, a fourth conductive contact is at the first face of the fourth die, and coupling the fourth die to the third die includes electrically coupling the third conductive contact to the fourth conductive contact.

Example 42 may include the subject matter of Example 41, and may further specify that coupling the third die to the second die includes securing the third die to the second die with a die attach film.

Example 43 may include the subject matter of any of Examples 41-42, and may further specify that an anisotropic conductive film is between the first face of the third die and the first face of the fourth die, and electrically coupling the third conductive contact to the fourth conductive contact includes bringing the first face of the fourth die proximate to the first face of the third die to compress the portion of the anisotropic conductive film between the third conductive contact and the fourth conductive contact.

Example 44 may include the subject matter of any of Examples 37-43, and may further include providing a mold compound around the first die and the second die on the package substrate.

1. An integrated circuit (IC) package, comprising:
a package substrate having a substrate conductive contact;
a first die coupled to the package substrate, wherein the first die has a first face and an opposing second face, the second face of the first die is between the first face of the first die and the package substrate, and the first die has a first conductive contact at the first face of the first die;
a second die coupled to the first die, wherein the second die has a first face and an opposing second face, the first face of the second die is between the first die and the second face of the second die, and the second die has a second conductive contact at the first face of the second die; and
a bondwire between the first conductive contact and the substrate conductive contact, wherein the bondwire is also in electrical contact with the second conductive contact.

2. The IC package of claim 1, further comprising:
conductive material between the first die and the second die to electrically couple the first conductive contact and the second conductive contact.

3. The IC package of claim 2, wherein the conductive material includes a wire bond bump.

4. The IC package of claim 3, wherein the conductive material includes an anisotropic conductive film.

5. The IC package of claim 1, wherein the first conductive contact is one of a plurality of first conductive contacts at the first face of the first die, the substrate conductive contact is one of a plurality of substrate conductive contacts at the package substrate, and individual ones of the first conductive contacts are wirebonded to associated individual ones of the substrate conductive contacts.

6-8. (canceled)

9. The IC package of claim 1, wherein the first conductive contact is one of a plurality of first conductive contacts at the first face of the first die, the second conductive contact is one of a plurality of second conductive contacts at the first face of the second die, and individual ones of the first conductive contacts are electrically coupled to associated individual ones of the second conductive contacts.

10. The IC package of claim 1, wherein the first die and the second die have mirror image structures.

11. The IC package of claim 1, wherein a die attach film is between the first die and the package substrate.

12. The IC package of claim 1, wherein the bondwire is a first bondwire, the substrate conductive contact is a first substrate conductive contact, the package substrate has a second substrate conductive contact, and the IC package further includes:
a third die coupled to the second die, wherein the third die has a first face and an opposing second face, the second face of the third die is between the first face of the first die and the second die, and the third die has a third conductive contact at the first face of the third die;
a fourth die coupled to the third die, wherein the fourth die has a first face and an opposing second face, the first face of the fourth die is between the third die and the second face of the fourth die, and the fourth die has a fourth conductive contact at the first face of the fourth die; and
a second bondwire between the third conductive contact and the second substrate conductive contact, wherein the bondwire is also in electrical contact with the fourth conductive contact.

13. The IC package of claim 12, further comprising:
conductive material between the third die and the fourth die to electrically couple the third conductive contact and the fourth conductive contact.

14. The IC package of claim 13, wherein the conductive material between the third die and the fourth die includes an anisotropic conductive film.

15. The IC package of claim 1, wherein a lateral extent of the first die is the same as a lateral extent of the second die.

16. The IC package of claim 1, wherein the first die is not laterally offset from the second die.

17. A computing device, comprising:
a circuit board; and
an integrated circuit (IC) package on the circuit board, wherein:
the IC package includes a package substrate with a substrate conductive contact,
the IC package includes a plurality of pairs of dies,
individual ones of the pairs of dies include a first die with a first face and an opposing second face and a second die with a first face and an opposing second face,
a first conductive contact is at the first face of individual first dies,
a second conductive contact is at the first face of individual second dies,
the first face of a first die in a pair is disposed between the second face of the first die and the first face of the second die,
the first face of a second die in a pair is disposed between the first face of the first die and the second face of the second die,
the first conductive contact and the second conductive contact are electrically coupled to a bondwire, and
the bondwire is attached to the substrate conductive contact.

18. (canceled)

19. The computing device of claim 17, wherein at least some of the dies in the plurality of pairs of dies include memory devices.

20. The computing device of claim 19, wherein the memory devices are three-dimensional memory devices.

21. The computing device of claim 17, wherein the IC package includes an anisotropic conductive film between the first face of the first die and the first face of the second die in a pair of dies.

22. A method of manufacturing an integrated circuit (IC) package, comprising: providing a first die on a package substrate, wherein the first die has a first face and an opposing second face, the second face of the first die is between the first face of the first die and the package substrate, and a first conductive contact is at the first face of the first die;
wirebonding the first conductive contact to a substrate conductive contact on the package substrate; and
coupling a second die to the first die, wherein the second die has a first face and an opposing second face, the first face of the second die is between the first face of the first die and the second face of the second die, a second conductive contact is at the first face of the second die, and coupling the second die to the first die includes electrically coupling the first conductive contact to the second conductive contact.

23. The method of claim 22, wherein providing the first die on the package substrate includes coupling the first die to the package substrate with a die attach film.

24. The method of claim 22, wherein an anisotropic conductive film is between the first face of the first die and the first face of the second die, and electrically coupling the first conductive contact to the second conductive contact includes bringing the first face of the first die proximate to the first face of the second die to compress the portion of the anisotropic conductive film between the first conductive contact and the second conductive contact.

25. (canceled)
